(19) United States
(12) Patent Application Publication
(10) Pub. No.: US 2009/0079068 A1
(43) Pub. Date: Mar. 26, 2009

(54) METHODS FOR ATTACHING A FLIP CHIP INTEGRATED CIRCUIT ASSEMBLY TO A SUBSTRATE

(75) Inventor: Emily Olanoff, San Diego, CA (US)

Correspondence Address: BAKER & MCKENZIE LLP;PATENT DEPARTMENT, 2001 ROSS AVENUE, SUITE 2300, DALLAS, TX, 75201, US

(73) Assignee: NEOLOGY, INC., Poway, CA (US)

(21) Appl. No.: 12/177,004

(22) Filed: Jul. 21, 2008

Related U.S. Application Data
(60) Provisional application No. 60/950,839, filed on Sep. 26, 2007.

(51) Int. Cl. H01L 21/60; H01L 23/498

(52) U.S. Cl. 257/737; 438/613; 257/E21.508; 257/E23.068

(57) ABSTRACT

A method for fabricating an integrated circuit assembly, comprises forming a conductive material pattern on a substrate using a process in which the conductive material in wet when formed, the conductive material pattern comprising contact points, before curing the conductive material, placing a integrated circuit comprising contact bumps on the substrate such that the bumps come in contact with the contact points of the conductive material pattern, and allowing the conductive material cure such that the conductive material forms a bond with the bumps.

### CROSS REFERENCE TO RELATED APPLICATIONS

This application claims the benefit under 35 U.S.C. 119(e) of U.S. Provisional Patent Application Ser. No. 60/950,839 filed Jul. 19, 2007 and entitled “Methods for Attaching a Flip Chip Integrated Circuit Assembly to a Substrate,” which is incorporated herein in its entirety as if set forth in full.

### BACKGROUND

1. Field of the Invention

The embodiments described herein are related to integrated circuit assemblies and more particularly, to systems and methods for attaching a flip chip integrated circuit (IC) to a substrate.

2. Background of the Invention

A flip chip is one type of mounting used for semiconductor devices, such as IC chips, which does not require any wire bonds. Instead, additional wafer processing steps deposit solder bumps on the chip pads. It is also common to use metallic plated bumps, or to bond metallic stud bumps on the chip pads. The bumps can then be used to connect directly to the associated external circuitry. The external circuitry is generally included on some form of substrate such as a printed circuit board. In the case of a Radio Frequency Identification (RFID) device, the substrate can be a substrate on which an antenna is formed. For example, passive RFID “tags” often use a flexible substrate, such as a plastic substrate onto which an antenna has been formed using conductive material. Thus, the IC chip must be attached to the antenna terminals on the flexible substrate.

In typical semiconductor fabrication systems, chips are built up in large numbers on a single large “wafer” of semiconductor material, typically silicon. The individual chips are patterned with small pads of metal near their edges that serve as the electrical connections to an eventual mechanical carrier. The chips are then cut out of the wafer and attached to their carriers, typically with small wires. These wires eventually lead to pins on the outside of the carriers, which are attached to the rest of the circuitry making up the electronic system.

The processing of a flip chip wafer is similar to conventional IC fabrication; however near the end of the process, the attachment pads are “metalized” to provide an electro/mechanical connection to the substrate. This is typically achieved by the creation of solder bumps, metallic plated bumps or metallic stud bumps as noted above. The chips are then cut out of the wafer as normal. No additional processing is required, and there is no mechanical carrier.

To attach the flip chip into a circuit, it is inverted to bring the “metalized” bumps, or standoffs down onto the pad locations on the underlying electronics or circuit board. The flip chip is permanently attached to the substrate using one of several methods, with the most common methods being a thermal cure, applied pressure, or an ultrasonic process.

The above process results in a small space between the chip's circuitry and the surface of the underlying electronics or circuit board. In most cases an electrically-insulating adhesive is then “underfilled” into this space to provide a stronger mechanical connection, to provide a heat bridge, and to ensure the connection joints are not stressed due to differential heating of the chip and the rest of the system. The resulting completed assembly, is often referred to as a Chip Scale Package (CSP), and is much smaller than a traditional carrier-based system, because the chip sits directly on the circuit board. In fact, a CSP is much smaller than a traditional carrier both in area and height.

When a flip chip IC has solder balls, a traditional solder reflow process will provide a secure electrical and mechanical connections to the substrate. When plated bumps, or stud bumps are used, however, they can provide a standoff height from the circuit board, but cannot use a reflow process. Instead, the use of isotropic conductive adhesive or a Z-axis conductive material, e.g., anisotropic conductive adhesive, anisotropic conductive film, and anisotropic conductive paste, are used to provide the electrical and/or mechanical connection to the substrate. Anisotropic conductive adhesives, films, or pastes will typically require both a thermal and compression curing process to provide a conductive path only in the Z direction, but avoid conduction in the x-y plane. The compression allows metallic particles suspended in the media to become a conductive path in the Z direction.

A problem can arise when the height of the bumps becomes smaller than about 25 microns. In such cases, it can become difficult to achieve a reliable connection, because the small gap between the circuitry on the IC and the surface of the substrate can only accommodate very thin layers of material for connecting the bumps with the circuitry on the substrate. If too much material is used, then unintended interaction between the IC and the circuitry on the substrate can occur, which will produce faults, short circuits, etc.

For circuits used in RFID products, especially in the Ultra High Frequency (UHF) band or higher, the small bump height presents even greater challenges. The use of additional conductive media between the antenna and the RFID IC can cause serious RF losses, which can affect the performance of the RFID product. In the RFID example, as the bump height of the RFID IC becomes smaller, the potential for interaction between the antenna pattern on the substrate and the IC can become a critical concern. While having a relatively large physical gap between the antenna on the substrate and the IC can minimize the interaction, there is a form factor penalty due to the larger product thickness. Also, for anisotropic materials, the Z axis conductive materials may be too thick to allow the IC bumps to compress the particles close together to achieve a conductive path.

### SUMMARY

A method for assembling an RFID tag including a flip chip IC comprises forming an antenna on a substrate using a conductive material such as a conductive ink and then immediately placing the flip chip IC onto the wet material to form the conductive contact between the IC and the antenna. As the conductive material cures it will adhere the IC to the substrate, thus eliminating the need for additional material and processing steps for attaching the IC to the antenna.

In one aspect, the conductive material can be screen printed on the substrate and the flip chip is placed into the wet ink.

In another aspect, the conductive material with attached flip chip can be allowed to cure, and then a non-conductive under-fill, or encapsulation material can be applied and cured.

In still another aspect, the non-conductive under-fill, or encapsulation can be applied immediately after flip chip attachment and cured along with the conductive material.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIGS. 1A-1C are diagrams illustrating an example process for assembling an RFID device;

FIG. 1D is a cross sectional view of an RFID device assembled using the process of FIGS. 1A-1C;

FIGS. 2A-2B are diagrams illustrating an example process for assembling an RFID device in accordance with one embodiment; and

FIG. 2C is a cross sectional view of an RFID device assembled using the process of FIGS. 2A-2B;

### DETAILED DESCRIPTION

The systems and methods described below relate to the assembly of RFID devices that use flip chip ICs; however, it will be understood that the systems and methods described herein are not necessarily limited to the assembly of RFID tags.

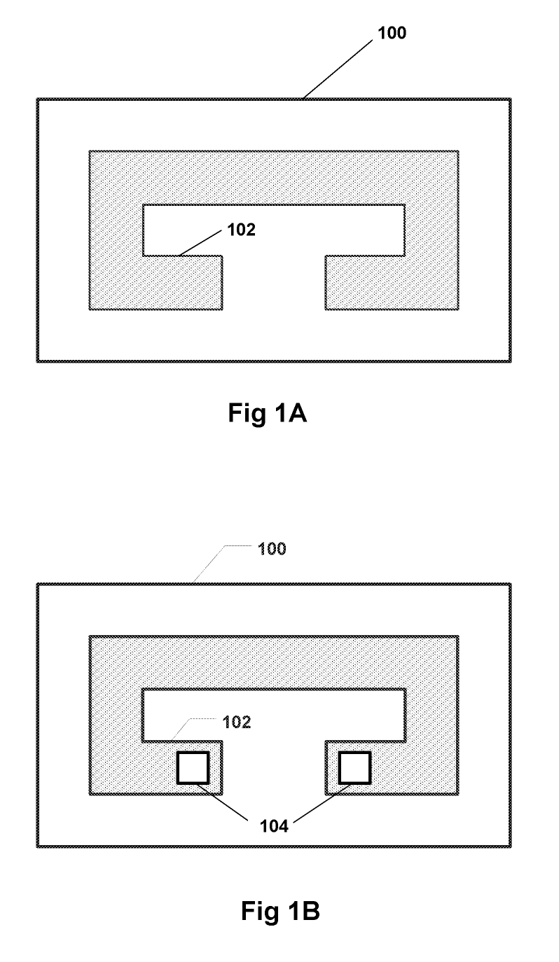

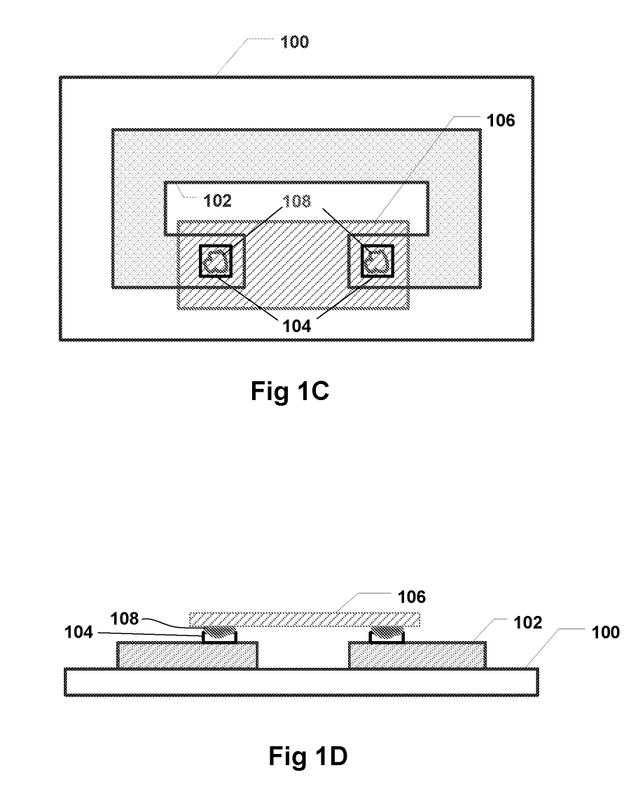

FIGS. 1A-1C are diagrams illustrating a conventional process for assembling a flip chip IC 106 to a substrate 100 such as a substrate comprising an antenna 102. It will be understood that the diagrams are not necessarily to scale, nor are various elements illustrated in relative proportion. Rather, it will be clear that the diagrams are presented by way of example to illustrate the various process steps.

First, as illustrated in FIG. 1A, an antenna pattern 102 can be formed on substrate 100. Substrate 100 can be a flexible substrate formed from a plastic or other flexible non-conductive material. In certain embodiments, substrate 100 can be a rigid substrate if required. Antenna pattern 102 can, for example, be formed using a conductive ink. In such instances, antenna pattern 102 can actually be printed directly on substrate 100. For example, a screen printing process can be used to print antenna pattern 102.

Referring to FIG. 1B, antenna pattern 102 is typically allowed to cure, and then a conductive material, such as an isotropic conductive adhesive or a Z-axis conductive material, e.g., anisotropic conductive adhesive, anisotropic conductive film, or anisotropic conductive paste 104, is then applied to the antenna terminals.

Referring to FIG. 1C, a flip chip IC 106 with, e.g., with solder balls 108 is then placed on substrate 100 so that solder balls 108 make contact with conductive material 104. Conductive material 104 is then allowed to cure, adhering IC 106 to substrate 100 and creating a conductive path between antenna 102 and solder balls 108.

FIG. 1D is a cross sectional view of the tag as assembled to this point. As can be seen, when IC 106 is placed onto conductive material 104, solder balls 108 will both compress material 104 and insert slightly into material 104. A non-conductive material (not shown) can then be used to under-fill the areas under IC 106 and above substrate 100. Alternatively, or in addition, a non-conductive material can be used to encapsulate IC 106.

It should be noted that the conductive material, e.g., ink used to form pattern 102 is allowed to cure, so that substrates 100 can then be placed onto a reel and used for reel-to-reel assembly processing. In other words, in order to speed assembly, components are often placed onto a reel so they can then be advanced using automated machinery after each assembly. Thus, in a conventional process, IC's 106 are typically provided on a reel for assembly and so are substrates 100. But if substrates 100 are placed onto a reel, then the material used for antenna patterns 102 must be dry so that they are not smeared, or otherwise effected.

In a conventional process, such as that illustrated above, a very thin layer of conductive material 104 is required, however, when the bump height of solder balls 108 is less than about 25 microns. Otherwise, unintended interaction between IC 106 and antenna 102 can occur. Unfortunately, conventional materials and process cannot reliable produce the thin layer of conductive material needed and provide the required adhesion and conductive properties at the same time. Moreover, the need to use conductive material 104 creates several additional processing steps, i.e., the additional application and curing steps.

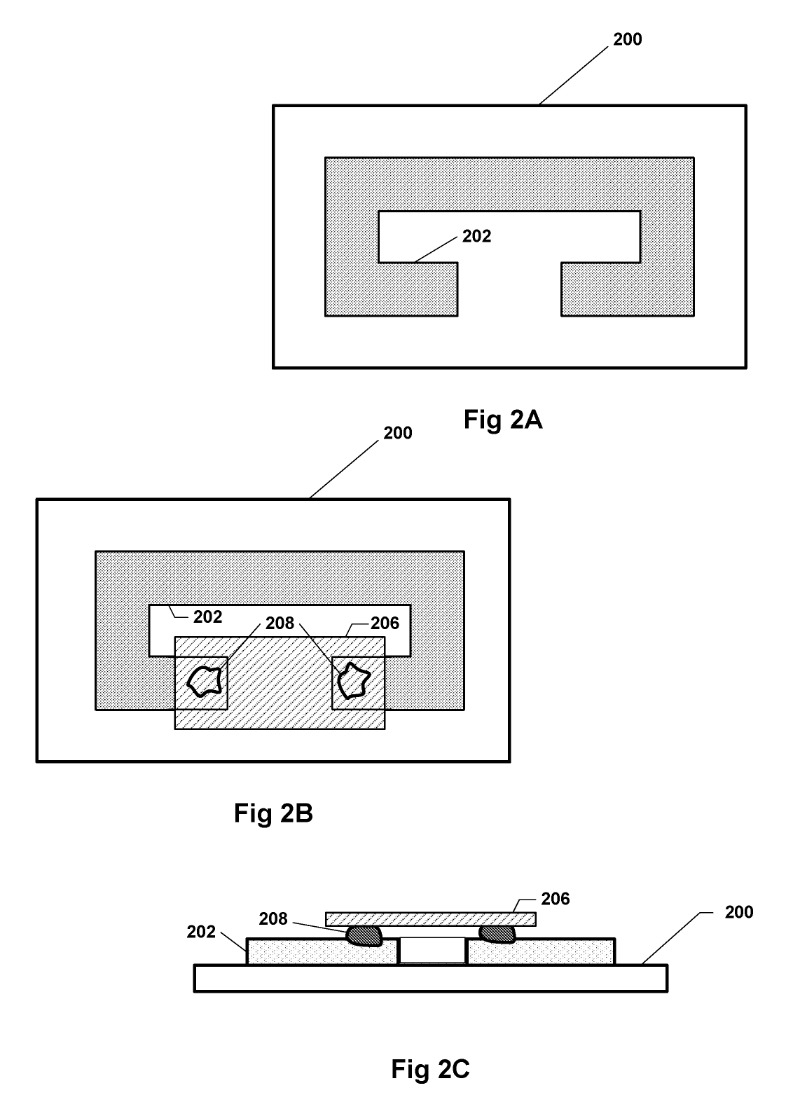

FIGS. 2A-2B are diagrams illustrating an example process for assembling a flip chip IC 206 to a substrate 200 such as a substrate comprising an antenna 202 in accordance with one embodiment. Again, it will be understood that the diagrams are not necessarily to scale, nor are various elements illustrated in relative proportion. Rather, it will be clear that the diagrams are presented by way of example to illustrate the various process steps.

Using the process illustrated in FIGS. 2A and 2B results in a reduction of the material and associated processing steps required. The reduction of material and mass between the IC and the antenna allows functional RFID devices to be assembled, even when the bump height of the IC is very small, i.e., less than about 25 microns. In the process of FIGS. 2A and 2B, antenna substrate 200 can be transported into the flip chip pick and place operation before the antenna conductive material is cured. In other words, the flip chip pick and place process occurs immediately after the conductive material is screen printed as illustrated in FIG. 2A, and while the material is still wet.

Referring to FIG. 2B, since no curing of conductive antenna pattern 202 occurs, it remains wet as IC 206 is placed. Thus, after pattern 202 is formed, and before the material cures, IC 206 can be placed, such that balls 208 come in contact with the terminals of antenna pattern 202. Antenna conductive material 202 will hold IC 206 in place as material 202 cures.

Referring to FIG. 2C, it can be seen that balls 208 will insert slightly into material 202. As material 202 cures, it will then adhere IC 206 to substrate 200 and provide a direct, conductive path between antenna pattern 202 and balls 208.

Once placement of IC 206 is completed, the assembly process can continue in either of two processes: 1) The antenna/IC assembly can be cured, and then protected with a nonconductive adhesive (not shown), i.e., an under-fill and/or encapsulant; or 2) a nonconductive adhesive (not shown), i.e., an under-fill and/or encapsulant, can be immediately applied and then all materials can be cured simultaneously.

It should be noted that the processes described are not limited to flip chips with short standoffs. It should also be apparent that skipping the application of a conductive epoxy will reduce the manufacturing cost of any size flip chip, which should reduce product completion time, material cost, and eliminates a material deposition and a cure stage.

Substrate 200 can be a flexible substrate used to construct, e.g., a RFID sticker or label tag; however, substrate 200 can also be a more rigid substrate used, e.g., for the fabrication of a contact-less smart card, or similar device. In fact, the processes described herein can be quite beneficial in the manufacture of smart cards. The ability to reduce the bump height requirement by eliminating the use of, or need for isotropic conductive paste will aid in keeping the card within the constraint of maximum card thickness. Further, the elimination of localized thermo compression bonding required for an anisotropic material can help to maintain the integrity of the card substrate. Still further, cards are typically composed of polycarbonate or polyvinylchloride, which melt and deform at the higher temperatures typically used for the anisotropic curing in a conventional process, a step that is eliminated in the processes described herein.

While certain embodiments have been described above, it will be understood that the embodiments described are by way of example only. Accordingly, the embodiments should not be limited based solely on the described embodiments. Rather, the embodiments describe herein should only be limited in light of the claims that follow when taken in conjunction with the above description and accompanying drawings.

What is claimed:

1. A method for fabricating an integrated circuit assembly, comprising:
forming a conductive material pattern on a substrate using a process in which the conductive material in wet when formed, the conductive material pattern comprising contact points;
before curing the conductive material, placing a integrated circuit comprising contact bumps on the substrate such that the bumps come in contact with the contact points of the conductive material pattern; and
allowing the conductive material cure such that the conductive material forms a bond with the bumps.

2. The method of claim 1, wherein the integrated circuit is a flip-chip integrated circuit.

3. The method of claim 1, wherein the integrated circuit assembly is a Radio Frequency Identification (RFID) assembly.

4. The method of claim 1, wherein the bumps include solder bumps.

5. The method of claim 1, wherein the bumps include metallic plated bumps.

6. The method of claim 1, wherein the bumps include metallic stud bumps.

7. The method of claim 1, further comprising applying an under-fill or encapsulate and then allowing the entire assembly including the conductive material to cure.

8. The method of claim 1, further comprising applying an under-fill or encapsulate after the conductive material is allowed to cure.

9. The method of claim 1, wherein the conductive material pattern is an antenna pattern.

10. The method of claim 1, wherein the process is carried out with a flip-chip pick and place machine.

11. The method of claim 1, wherein the conductive material pattern is formed via a screen printing process.

12. An integrated circuit assembly, comprising:
a substrate;
a conductive material pattern formed on the substrate; and
an integrated circuit comprising contact bumps interfaced with the conductive material pattern via a bond formed between the contact bumps and the conductive material pattern.

13. The integrated circuit assembly of claim 12, wherein the conductive material pattern is an antenna pattern.

14. The integrated circuit assembly of claim 12, wherein the integrated circuit is a flip-chip integrated circuit.

15. The integrated circuit assembly of claim 12, wherein the integrated circuit assembly is a Radio Frequency Identification (RFID) assembly.

16. The integrated circuit assembly of claim 12, wherein the bumps include solder bumps.

17. The integrated circuit assembly of claim 12, wherein the bumps include metallic plated bumps.

18. The integrated circuit assembly of claim 12, wherein the bumps include metallic stud bumps.

19. The integrated circuit assembly of claim 12, further comprising a non-conductive under-fill between the integrated circuit and the substrate.

20. The integrated circuit assembly of claim 12, further comprising a capsule surrounding the integrated circuit.
